(19) United States
(12) Patent Application Publication
(10) Pub. No.: US 2012/0119342 A1
(43) Pub. Date: May 17, 2012

(54) ADVANCED QUAD FLAT NON-LEADED PACKAGE STRUCTURE AND MANUFACTURING METHOD THEREOF

(75) Inventors: Pao-Huei Chang Chien, Kaohsiung County (TW); Ping-Cheng Hu, Kaohsiung City (TW); Po-Shing Chiang, Kaohsiung County (TW); Wei-Lun Cheng, Kaohsiung City (TW); Hsueh-Te Wang, Kaohsiung City (TW); Hsiao-Chuan Chang, Kaohsiung City (TW); Tsung-Yueh Tsai, Kaohsiung County (TW); Yi-Shao Lai, Taipei County (TW); Ping-Feng Yang, Kaohsiung County (TW)

(73) Assignees: MediaTek Inc., Hsinchu (TW); ADVANCED SEMICONDUCTOR ENGINEERING, INC., Kaohsiung (TW)

(21) Appl. No.: 12/944,695

(22) Filed: Nov. 11, 2010

(51) Int. Cl. H01L 23/495; H01L 21/58; H01L 21/56

(52) U.S. Cl. 257/676; 438/127; 438/118; 257/E23.054; 257/E21.502

(57) ABSTRACT

The advanced quad flat non-leaded package structure includes a carrier, a chip, a plurality of wires, and a molding compound. The carrier includes a die pad and a plurality of leads. The inner leads of the leads are designed to possess incurved sidewalls for enhancing the adhesion between the inner leads and the surrounding molding compound.

### BACKGROUND OF THE INVENTION

1. Field of the Invention

The present invention generally relates to a package structure and a manufacturing method thereof. More particularly, the present invention relates to an advanced quad flat non-leaded (a-QFN) package structure and a manufacturing method thereof.

2. Description of Related Art

Quad flat package (QFP) family includes I-type (QFI), J-type (QFJ) and non-lead-type (QFN) packages, characterized by the shape of the leads of leadframes. Among them, the QFN package structures offer a variety of advantages, including reduced lead inductance, small-sized footprint, thinner profile and faster speeds for signal transmission. Thus, the QFN package has become one popular choice for the package structures and is suitable for the chip package with high-frequency (for example, radio frequency bandwidth) transmission.

For the QFN package structure, the die pad and surrounding contact terminals (lead pads) are fabricated from a planar lead-frame substrate. The QFN package structure generally is soldered to the printed circuit board (PCB) through the surface mounting technology (SMT). Accordingly, the contact terminals/pads of the QFN package structure need to be designed to fit well within the packaging process capabilities, as well as promote good long term joint reliability.

### SUMMARY OF THE INVENTION

The present invention is directed to an advanced quad flat non-leaded package structure and a manufacturing method thereof, which can help lessen lead fall-off concerns and enhance the product reliability.

The present invention provides an advanced quad flat non-leaded package structure having a carrier, a chip disposed on the carrier, a plurality of wires and a molding compound. The carrier includes a die pad and a plurality of leads, and the leads include a plurality of inner leads and a plurality of outer leads exposed by the molding compound. At least one inner lead includes a metal layer and a guard layer covering at least a portion of edges and sidewalls of the underlying metal layer. Further, at least one inner lead has incurved sidewalls, which are capable of increasing adhesion between the inner lead and the surrounding molding compound. The wires are disposed between the chip and the inner leads. The molding compound encapsulates the chip, the die pad, the wires and the inner leads.

According to embodiments of the present invention, the sidewalls of the inner lead may be designed to be incurved or curved for promoting the locking or wedging capability of the inner leads with the surrounding molding compound.

The present invention further provides a manufacturing method of an advanced quad flat non-leaded package structure. After providing a substrate having an upper surface and a lower surface, a first metal layer and a second metal layer are respectively formed on the upper surface and the lower surface of the substrate, a first etching process is performed to the upper surface of the substrate. Later, a guard layer is formed on the first metal layer to cover at least the edges and sidewalls of the first metal layer. A second etching process to the upper surface of the substrate, using the guard layer and the first metal layer as a mask, to form an accommodating cavity and a plurality of inner leads defined by a plurality of openings there-between. The inner leads have incurved sidewalls. Followed by providing a chip to the accommodating cavity of the substrate and forming a plurality of wires between the chip and the inner leads, a molding compound is formed over the substrate to encapsulate the chip, the wires, the inner leads, and filling the accommodating cavity and the openings between the inner leads. Afterwards, a third etching process using the second metal layer as an etching mask may be performed to etch through the substrate, until the molding compound filled inside the openings is exposed, so as to form a plurality of leads and a die pad.

According to embodiments of the present invention, the inner leads can be fabricated by forming the guard layer partially or fully covering the underlying first metal layer and patterning the substrate using both layers as the mask. Hence, taking advantage of the undercuts occurring during the etching, the obtained inner leads have incurved sidewalls, which increase the contact area between the inner leads and the molding compound.

In order to make the above and other features and advantages of the present invention more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1J are schematic cross-sectional views illustrating a manufacturing method of an advanced quad flat non-leaded (a-QFN) package structure according to an embodiment of the present invention.

FIGS. 1E′-1F′ show schematic, cross-sectional views of an exemplary portion for the a-QFN package structure depicted in FIGS. 1E-1F.

FIG. 2 shows a schematic cross-sectional view illustrating an advanced quad flat non-leaded (a-QFN) package structure according to an embodiment of the present invention.

FIGS. 3A through 3J are schematic cross-sectional views illustrating a manufacturing method of an advanced quad flat non-leaded (a-QFN) package structure according to another embodiment of the present invention.

FIGS. 3E′-3F′ show enlarged cross-sectional views of an exemplary portion for the a-QFN package structure depicted in FIGS. 3E-3F.

FIG. 4 shows a schematic cross-sectional view illustrating an advanced quad flat non-leaded (a-QFN) package structure according to another embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the descriptions to refer to the same or like parts.

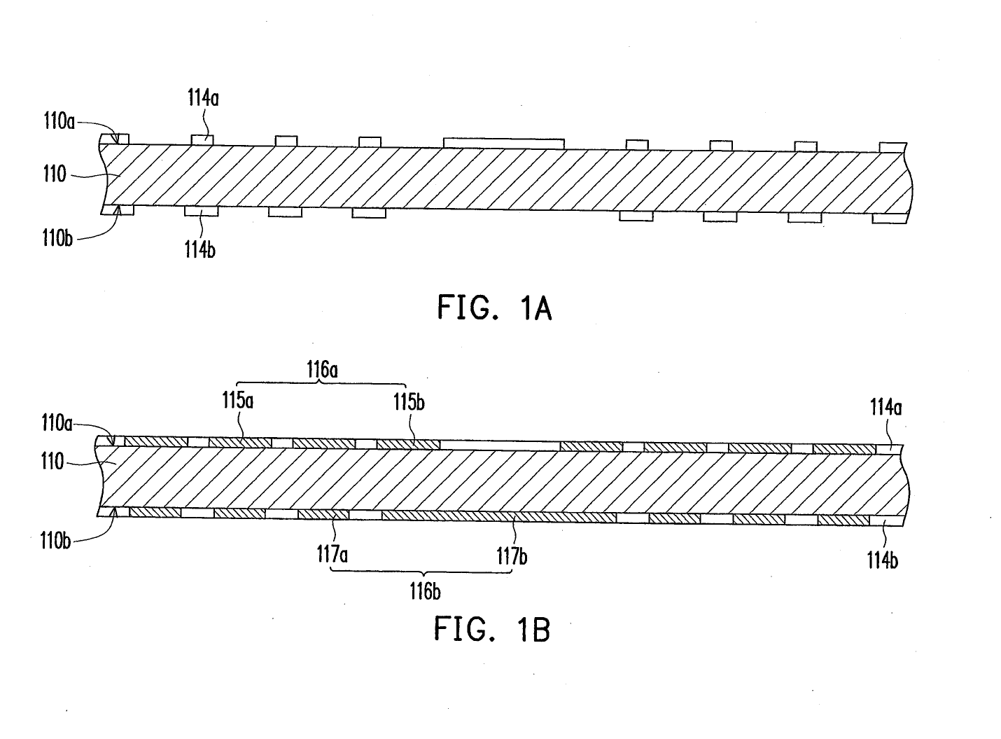

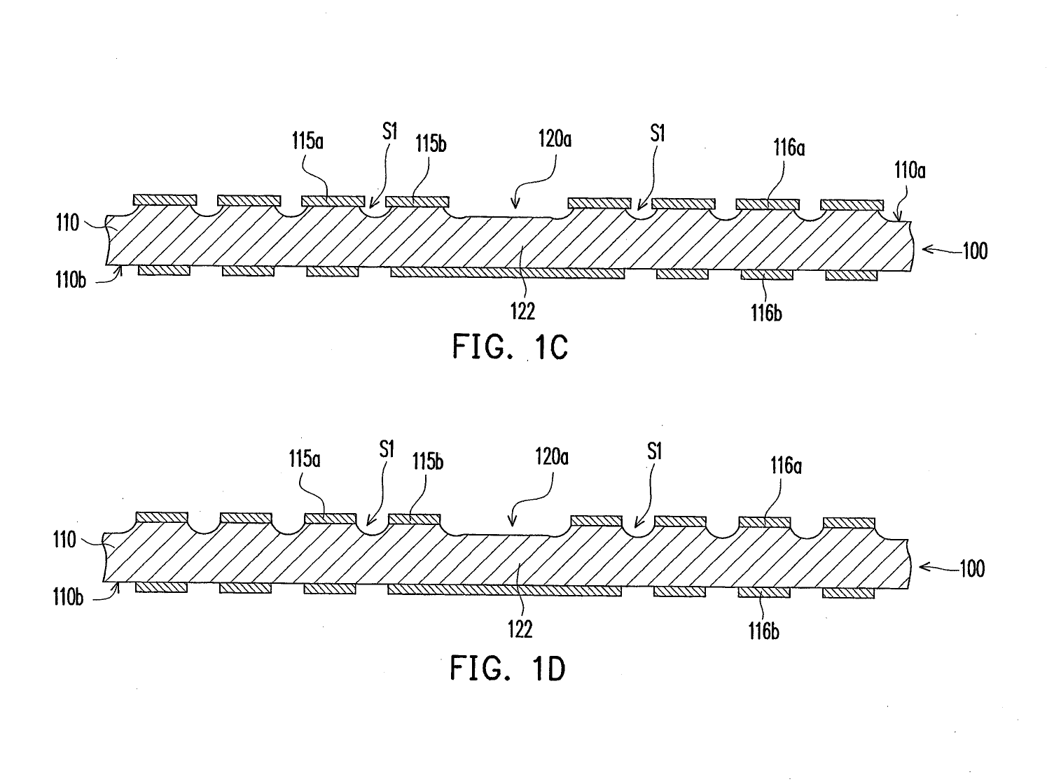

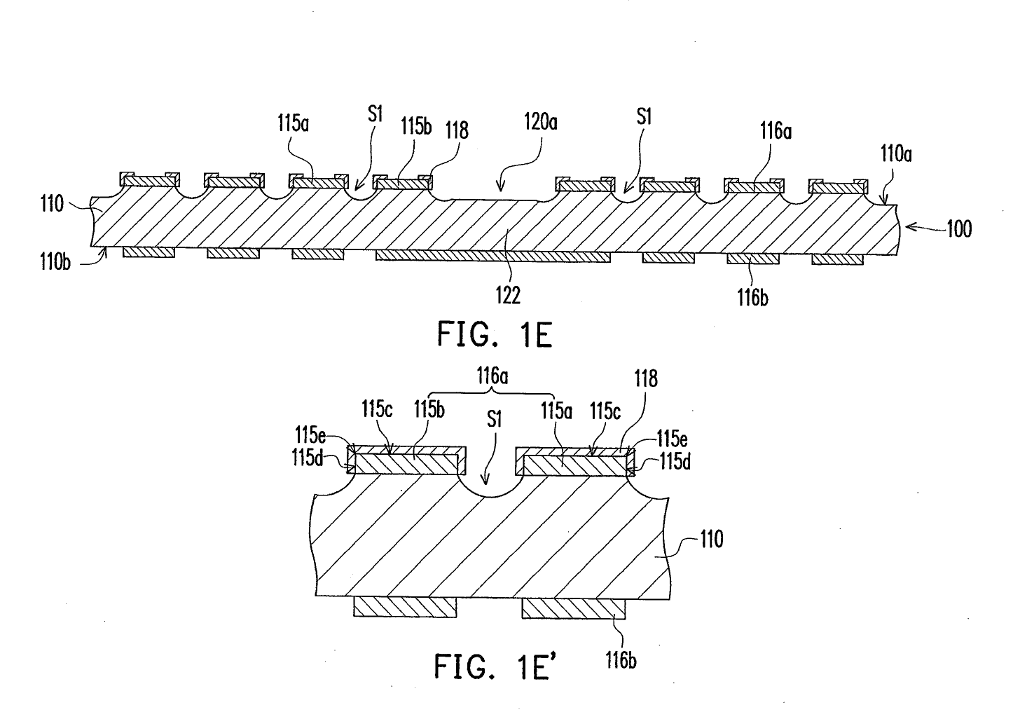

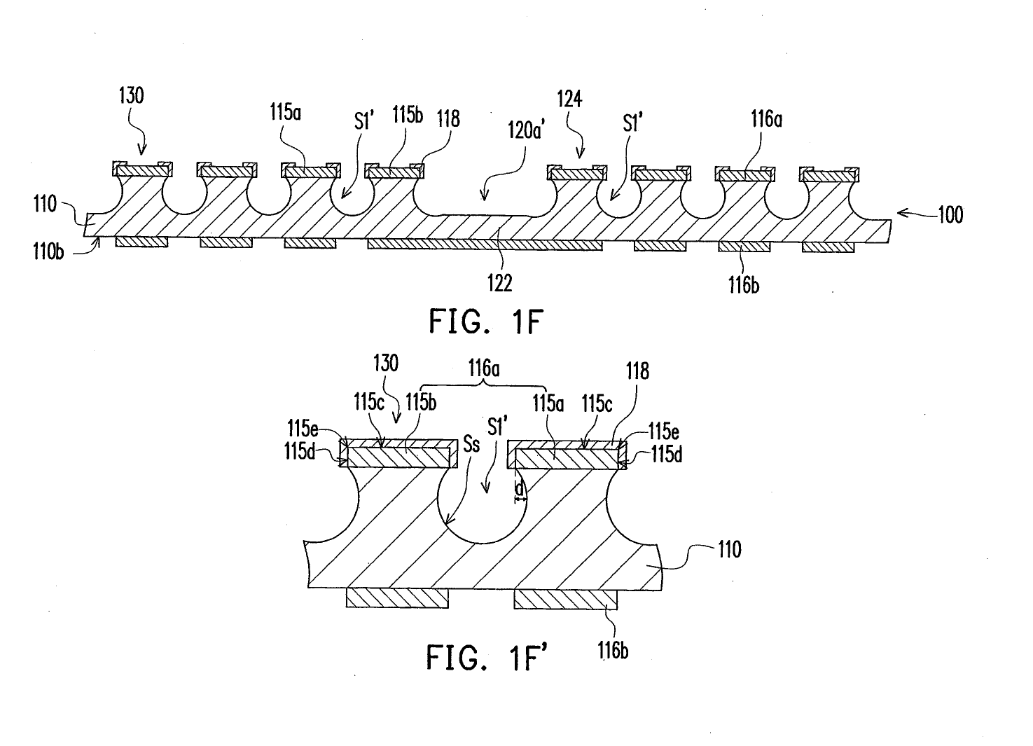

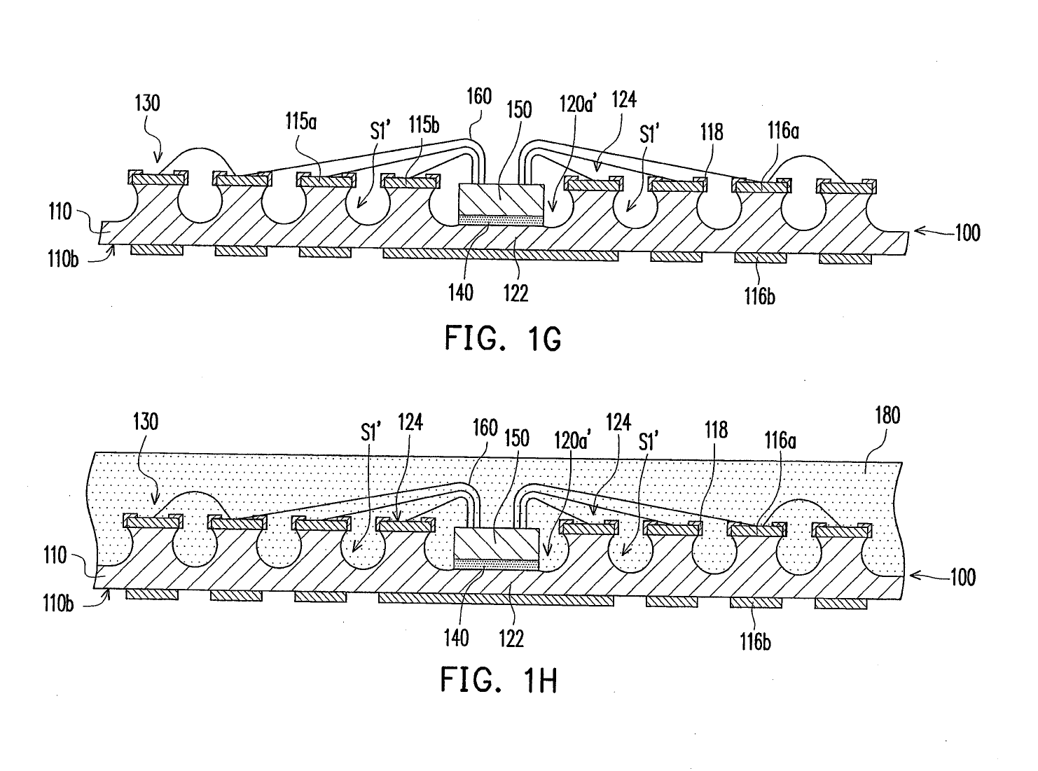

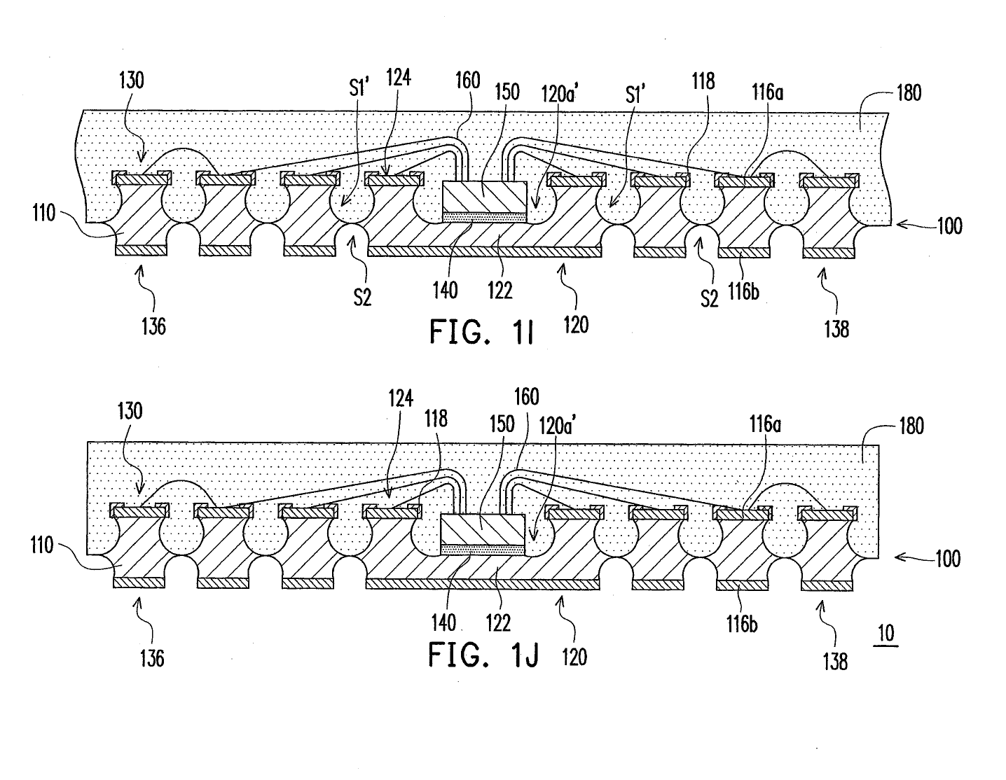

FIGS. 1A through 1J are schematic cross-sectional views illustrating a manufacturing method of an advanced quad flat non-leaded package structure according to an embodiment of the present invention.

As shown in FIG. 1A, a substrate 110 having the upper surface 110a and the lower surface 110b is provided. The material of the substrate 110 can be, for example, copper, a copper alloy, or other applicable metal materials. Next, still referring to the FIG. 1A, a first patterned photoresist layer 114a is formed on the upper surface 110a of the substrate 110, and a second patterned photoresist layer 114b is formed on the lower surface 110b of the substrate 110.

Next, referring to the FIG. 1B, using the first/second photoresist layers 114a/114b as masks, a first metal layer 116a is formed on the exposed portions of the upper surface 110a of the substrate 110 and a second metal layer 116b is formed on the exposed portions of the lower surface 110b of the substrate 110. In the present embodiment, the first metal layer 116a and the second metal layer 116b may be formed by, for example, plating. The first or second metal layer 116a/116b described herein may be composed of various groups of unconnected patterns or a continuous layer, depending on the pattern designs of the first or second patterned photoresist layer 114a/114b. The first metal layer 116a can be a Ni/Au layer, for example.

As shown in FIG. 1B, the first metal layer 116a includes a plurality of first metal portions 115a and at least a second metal portion 115b. The first metal portions 115a subsequently will be formed as inner leads 130 (as shown in FIG. 1F), while the second metal portion 115b will subsequently be formed as a ground ring 124 of the die pad 120 (as shown in FIG. 1I). Similarly, the second metal layer 116b includes a plurality of third metal portions 117a and at least a fourth metal portion 117b. The third metal portions 117a correspond to the subsequently to-be-formed outer leads 136 (as shown in FIG. 1I), while the second metal portion 117b corresponds to the subsequently to-be-formed die pad 120.

Next, referring to the FIG. 1C, the first photoresist layers 114a is removed. Then, a first etching process, such as an isotropic etching process, is performed to the upper surface 110a of the substrate 110 by using the first metal layer 116a as an etching mask, so as to remove portions of the substrate 110 and form at least a first cavity 120a and a plurality of first openings S1. The first etching process is a wet etching process, for example. As the first etching process is an isotropic etching process, undercuts can easily occur under the first metal layer 116a. Hence, as shown in FIG. 1D, a water-jet process is performed to cut off or remove portions of the first metal layer 116a right above the undercuts.

Afterwards, referring to the FIG. 1E or 1E′, a guard layer 118 is formed to at least cover edges and sidewalls of the first and second metal portions 115a/115b. FIG. 1E′ shows an enlarged cross-sectional view of an exemplary portion for the a-QFN package structure shown in FIG. 1E. The guard layer 118 may be formed by coating a filling material (not shown) to the first cavity 120a and the first openings Si and then plating a metal layer (not shown) over the first metal layer 116a, for example. Alternatively, the guard layer 118 in FIG. 1E′ not only covers (i.e. protects) the edges 115e and sidewalls 115d of the first and second metal portions 115a/115b but also covers the top surfaces 115c of the first and second metal portions 115a/115b. The material of the guard layer 118 can be gold or any suitable etching-resistant metal material, for example.

Then, referring to FIG. 1F or 1F′, a second isotropic etching process is performed to the upper surface 110a of the substrate 110 by using the guard layer 118 together with the first metal layer 116a as an etching mask, so as to remove portions of the substrate 110. Due to the existence of the guard layer 118, the sidewalls of the first metal layer 116a is protected during the second etching process. In this case, the patterns (or openings) of the first metal layer 116a are not tempered but the underlying openings become widen and deeper. FIG. 1F′ shows an enlarged cross-sectional view of an exemplary portion for the a-QFN package structure shown in FIG. 1F. The first cavity 120a is further etched into an accommodating cavity 120a′, while the first openings S1 are further etched into deeper first openings S1′. Defined by the openings S1′, a plurality of individual inner leads 130 is formed. The depth ratio of the first openings S1 and first openings S1′ may range from 1:3 to 1:4, for example. Since the second etching process is an isotropic etching process, the side profiles of the first openings S1′ are wider and undercuts can easily occur under the guard layer 118 and the first metal layer 116a. In this case, the sidewalls Ss of the first openings S1′ are excurved (curved outward when compared with the opening sidewalls after the first etching process), and the excurved distance “d” can be as large as about 0.5 microns, for example. On the other hand, the sidewalls Ss of the inner leads 130 are incurved (curved inward when compared with the inner lead sidewalls after the first etching process) and the incurved distance “d” (the horizontal distance from the sidewall of the first metal layer to the inner most sidewall of the inner lead) can be as large as about 0.5 microns, for example. In other words, the inner lead 130 has a narrow portion (i.e. neck) in the middle.

As described in the embodiments, the inner leads 130 take advantage of the formation of the undercuts to reinforce or optimize the locking capability of the inner leads toward the subsequently formed molding compound. Accordingly, the etching rate, selectivity of the second etching process can be finely tuned for optimal performances, so as to control the dimension or the profile of the openings and optimize the shapes of the lead patterns.

So far, the carrier 100 is roughly formed following the formation of the first metal layer 116a, the second metal layer 116b and patterning the substrate 110. The accommodating cavity 120a′ has a central portion 122 and a peripheral portion 124 disposed around the central portion 122. The inner leads 130 are disposed surrounding but separate from the peripheral portion 124. The inner leads 130 may be arranged in rows, columns or arrays. The peripheral portion 124 can function as the ground ring.

Next, referring to the FIG. 1G, at least a chip 150 is attached to the central portion 122 of the accommodating cavity 120a′ with an adhesive layer 140 in-between. Later, a plurality of wires 160 are provided between the chip 150, the ground ring 124 and the inner leads 130. In other words, the chip 150 is electrically connected to the ground ring 124 and the inner leads 130 through the wires 160.

Next, referring to the FIG. 1H, a molding compound 180 is formed to encapsulate the chip 150, the wires 160, the inner leads 130, the ground ring 124, and fill the accommodating cavity 120a′ and the first openings S1′.

Then, referring to the FIG. 1I, using the second metal layer 116b as an etching mask, a third etching process is performed toward the lower surface 110b of the carrier 100 to remove a portion of the substrate 110, so that the carrier 100 is etched through to expose the molding compound 180 filled inside the first openings S1′ and simultaneously form a plurality of second openings S2. Owing to the formation of the second openings S2, a plurality of outer leads 136 is defined and the inner leads 130 are electrically isolated from one another. That is, after the third etching process, a plurality of leads or contact terminals 138, each consisting of one inner lead 130 and the corresponding outer lead 136, is formed. Besides, the third etching process further defines at least a die pad 120 of the carrier 100. The die pad 120 is surrounded by the leads 138 and isolated from the leads 138 through the second openings S2. On the whole, the leads 138 are electrically isolated from one another through this etching process.

Afterwards, referring to FIG. 1J, a singulation process is performed, so that individual a-QFN package structures 10 are obtained.

In detail, in the present embodiment, the guard layer 118 protects at least the edges and sidewalls of the first patterned metal layer 116a during the second etching process (FIG. 1F or 1F′), wider openings S1′ are formed under the first metal layer 116a and sidewalls of the openings S1′ are excurved (due to the undercuts). Consequently, as the contact area between the inner leads 130 (having incurved sidewalls) and the surrounding molding compound 180 is increased, binding between the inner leads 130 and the surrounding molding compound 180 can be enhanced, so that the contact terminals 138 will not fall off during the surface mounting processing or other subsequent process, and the product reliability can be greatly improved. For the a-QFN package structure 10 in the present embodiment, the fall-off issues of the contact terminals 138 can be lessened and the mold locking capability can be of the contact terminals (or leads) can be enhanced.

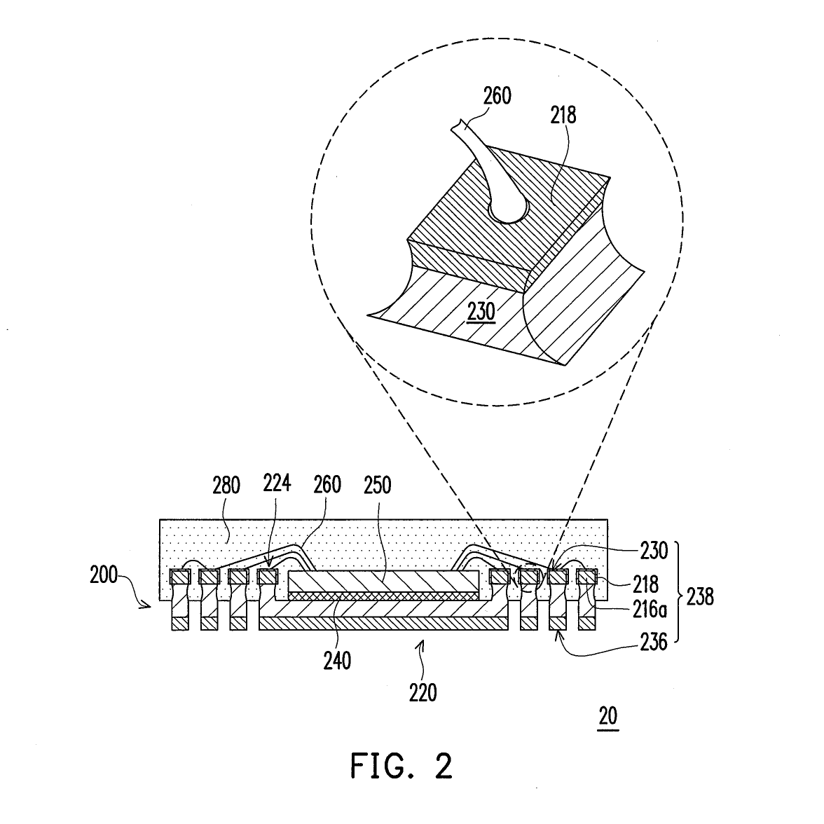

FIG. 2 is a schematic cross-sectional view illustrating an advanced quad flat non-leaded (a-QFN) package structure according to an embodiment of the present invention, while one of the inner lead of the a-QFN package structure is shown in an enlarged 3D view on the right. Referring to FIG. 2, in the present embodiment, an advanced quad flat non-leaded (a-QFN) package structure 20 includes a carrier 200, a chip 250, a plurality of wires 260 and a molding compound 280.

The carrier 200 in the present embodiment is, for example, a leadframe. In detail, the carrier 200 includes a die pad 220 and a plurality of leads (contact terminals) 238. The leads 238 include a plurality of inner leads 230 and a plurality of outer leads 236. In FIG. 2, three columns/rows of the contact terminals 238 are schematically depicted. Specifically, the leads 238 are disposed around the die pad 220, and the material of the leads 238 may comprise nickel, gold, palladium or a combination thereof, for example. The inner leads and the outer leads are defined by the molding compound; that is, the portions of the leads that are encapsulated by the molding compound are defined as the inner leads, while the outer leads are the exposed portions of the leads.

Further, the die pad 220 of the carrier 200 further includes at least a ground ring 224. The ground ring 224 is electrically connected to the chip 250 through wires 260. As the ground ring 224 is connected to the die pad 220, the die pad together with the ground ring may function as the ground plane. It should be noted that the position, the arrangement and the amount of the leads 238, relative to the ground ring 224 and the die pad 220 as shown in FIG. 2 are merely exemplificative and should not be construed as limitations to the present invention.

In more details, as shown in the three-dimensional enlarged view at the right, the inner lead 230 in the present embodiment has a guard layer 218 covering at least the edges and the sidewalls of the metal layer 216a. However, the guard layer 218 can be ring-shaped (covering only the edges and the sidewalls) or cap-shaped (covering the top surface and the sidewalls of the metal layer 216a), for example. In the present embodiment, the arrangement or the shape of the inner leads 230 and/or the guard layer 218 are merely exemplificative.

In FIG. 2, the outer leads 236 are exemplarily depicted with vertical sidewalls but the inner leads 230 are exemplarily depicted with curved sidewalls, in order to emphasize the differences between the profiles or outlines of first and second opening S1′/S2. However, it is understood that the outer leads 236 do not necessarily have vertical sidewalls. Due to the existence of the guard layer, the undercuts occurring below the metal layer leads to more incurved sidewalls of the inner leads, which significantly increase the binding between the leads and the molding compound.

In addition, the molding compound 280 of the a-QFN package structure 20 in the present embodiment encapsulates the chip 250, the wires 260, and the inner leads 230 and fills the gaps between the inner leads 230, while the outer leads 236 and the bottom surface of the die pad 220 are exposed. A material of the molding compound 280 is, for example, epoxy resins or other applicable polymer material.

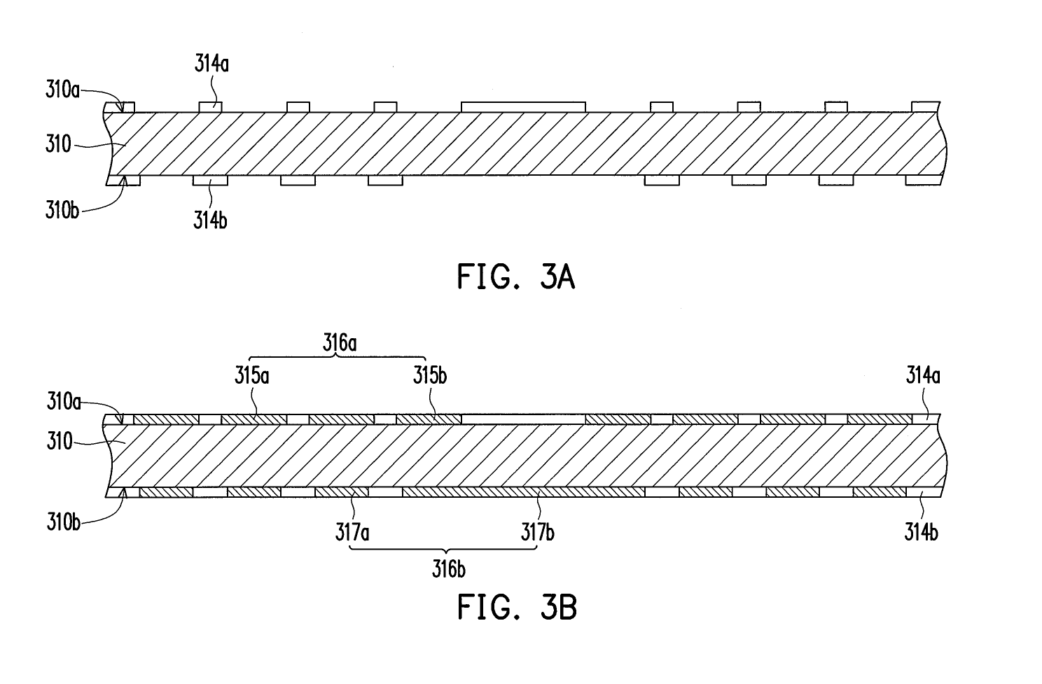

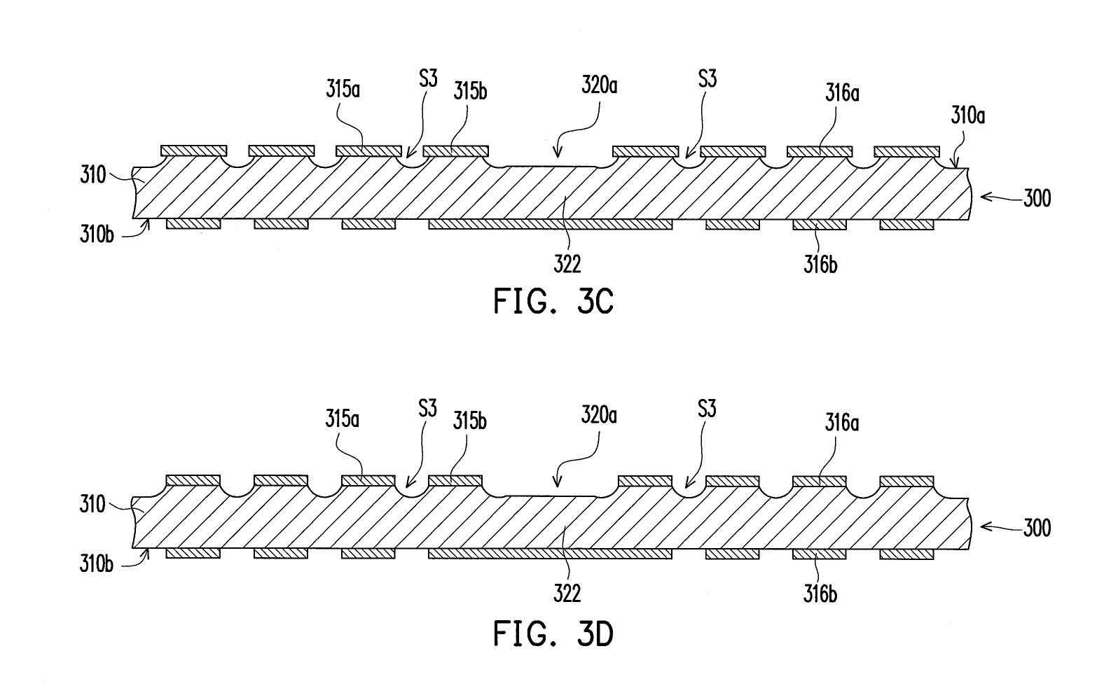

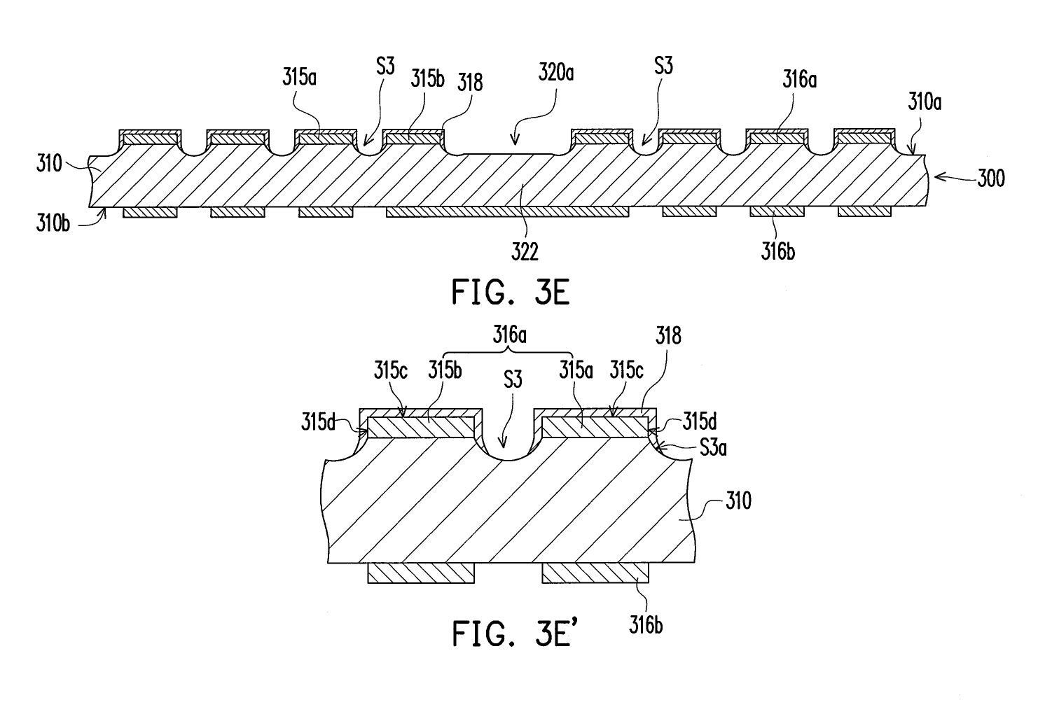

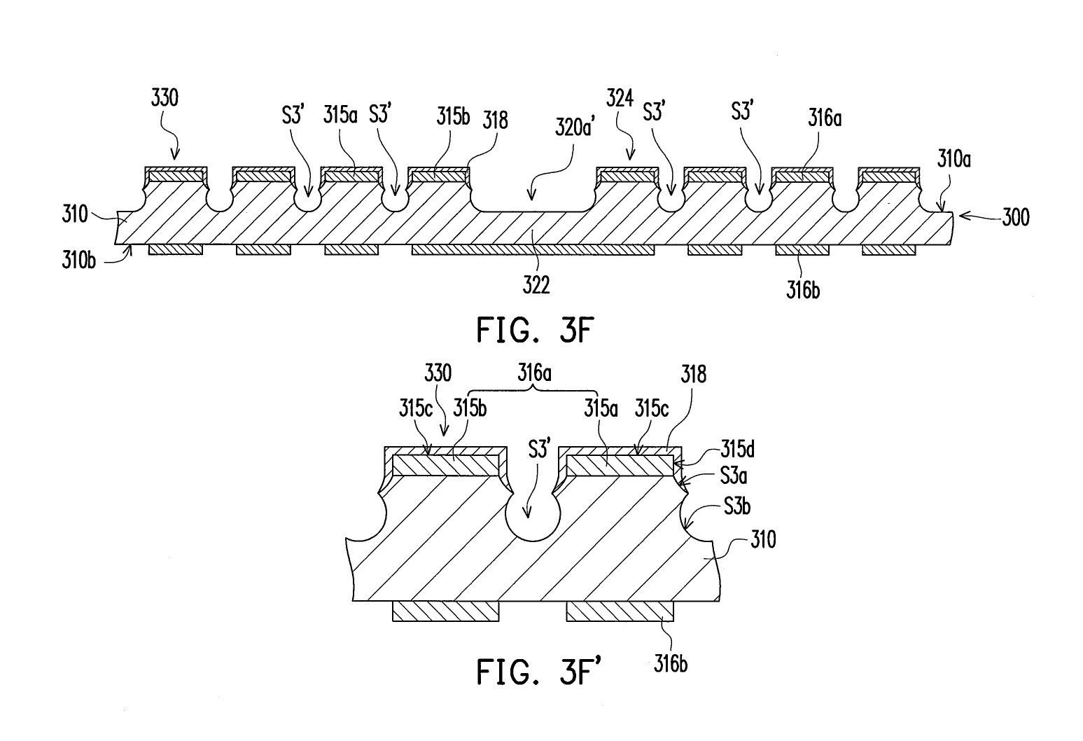

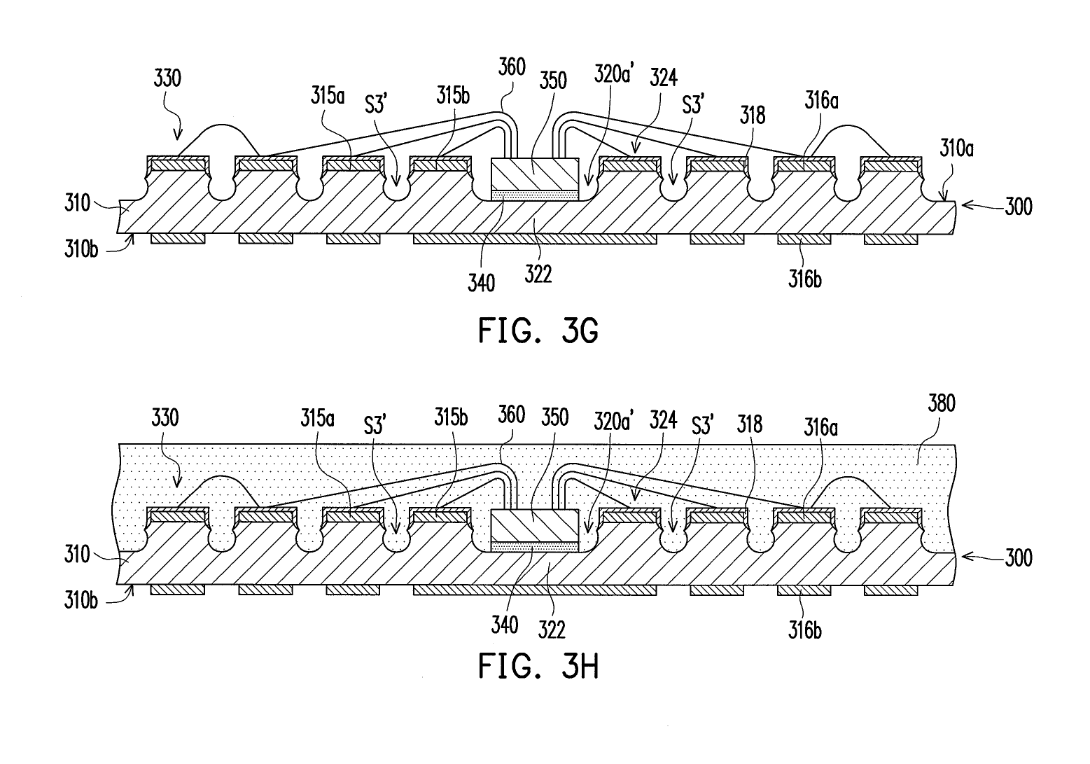

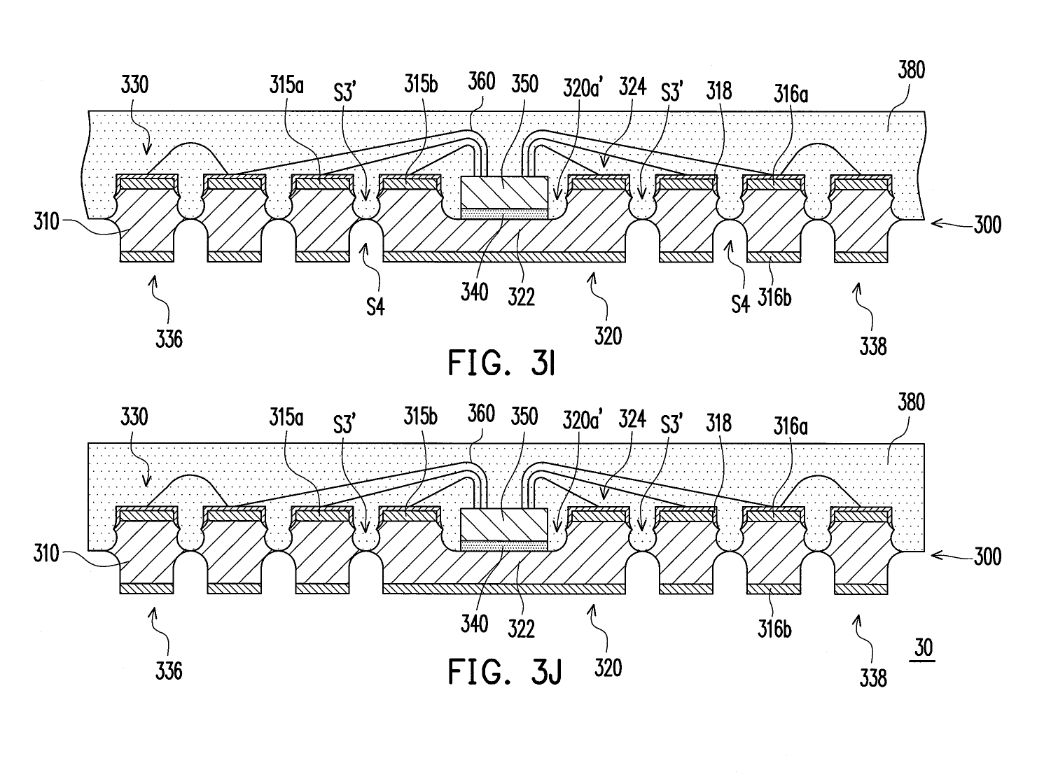

FIGS. 3A through 3J are schematic cross-sectional views illustrating a manufacturing method of an advanced quad flat non-leaded package structure according to another embodiment of the present invention.

As shown in FIG. 3A, a substrate 310 having the upper surface 310a and the lower surface 310b is provided. The material of the substrate 310 can be, for example, copper, a copper alloy, or other applicable metal materials. Next, still referring to the FIG. 3A, a first patterned photoresist layer 314a is formed on the upper surface 310a of the substrate 310, and a second patterned photoresist layer 314b is formed on the lower surface 310b of the substrate 310.

Next, referring to the FIG. 3B, using the first/second photoresist layers 314a/314b as masks, a first metal layer 316a is formed on the exposed portions of the upper surface 310a of the substrate 310 and a second metal layer 316b is formed on the exposed portions of the lower surface 310b of the substrate 310. In the present embodiment, the first metal layer 316a and the second metal layer 316b may be formed by, for example, plating. The first or second metal layer 316a/316b described herein may be composed of various groups of unconnected patterns or a continuous layer, depending on the pattern designs of the first or second patterned photoresist layer 314a/314b. The first metal layer 316a can be a Ni/Au layer, for example.

As shown in FIG. 3B, the first metal layer 316a includes a plurality of first metal portions 315a and at least a second metal portion 315b. The first metal portions 315a subsequently will be formed as inner leads 330 (as shown in FIG. 3F), while the second metal portion 315b will subsequently be formed as a ground ring 324 of the die pad 320 (as shown in FIG. 31). Similarly, the second metal layer 316b includes a plurality of third metal portions 317a and at least a fourth metal portion 317b. The third metal portions 317a correspond to the subsequently to-be-formed outer leads 336 (as shown in FIG. 3I), while the second metal portion 317b corresponds to the subsequently to-be-formed die pad 320.

Next, referring to the FIG. 3C, the first and second photoresist layers 314a/314b are removed. Then, a first etching process, such as an isotropic etching process, is performed to the upper surface 310a of the substrate 310 by using the first metal layer 316a as an etching mask, so as to remove portions of the substrate 310 and form at least a first cavity 320a and a plurality of first openings S3. The first etching process is a wet etching process, for example. As the first etching process is an isotropic etching process, undercuts can easily occur under the first metal layer 316a. Hence, as shown in FIG. 3D, a water-jet process is performed to cut off or remove portions of the first metal layer 316a right above the undercuts.

Afterwards, referring to the FIG. 3E or 3E′, a guard layer 318 is formed to cover the first and second metal portions 315a 1315b and partially cover the upper sidewalls of the first openings S3. FIG. 3E′ shows an enlarged cross-sectional view of an exemplary portion for the a-QFN package structure shown in FIG. 3E. The guard layer 318 may be formed by coating a filling material (not shown) to the first cavity 320a and the first openings S3 and then plating a metal material layer (not shown) over the first meta layer 316a, for example. The guard layer 318 in FIG. 3E′ not only covers (i.e. protects) the top surfaces 315c and sidewalls 315d of the first and second metal portions 315a/315b but also partially covers the sidewall surfaces S3a of the first openings S3 (and the sidewall of the cavity 320a). Herein, as undercuts occur, the sidewalls S3a of the openings S3 are curved. The material of the guard layer 318 can be gold or any suitable etching-resistant metal material, for example.

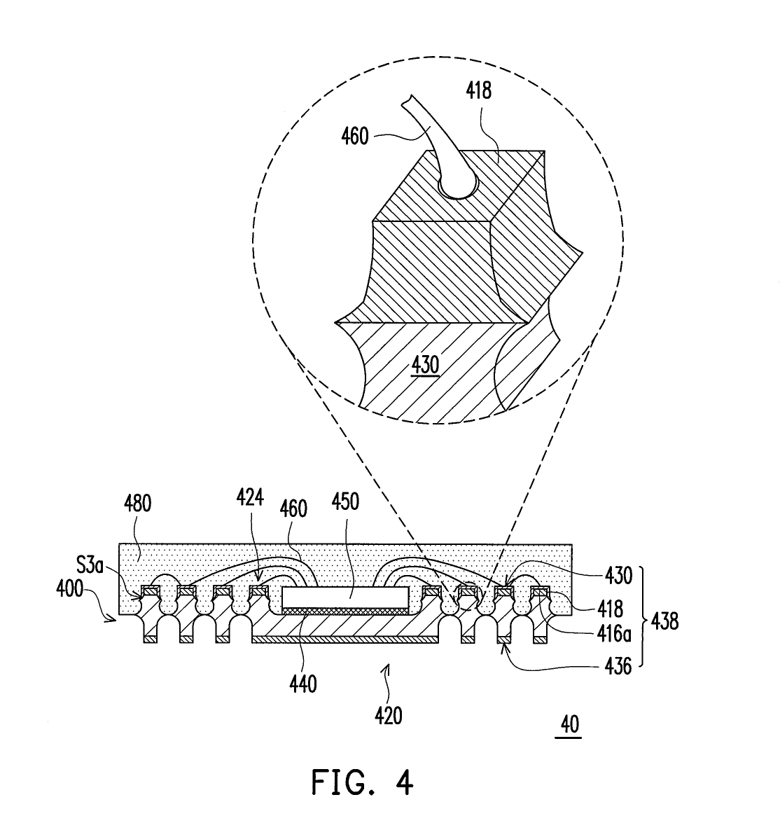

Then, referring to FIG. 3F or 3F′, a second etching process is performed to the upper surface 310a of the substrate 310 by using the guard layer 318 together with the first metal layer 316a as an etching mask, so as to remove portions of the substrate 310. Due to the existence of the guard layer 318, the sidewalls of the first metal layer 316a and a portion of the opening sidewalls S3a are protected during the second etching process. In this case, the patterns of the first metal layer 316a are not tempered but the underlying openings become deeper. FIG. 3F′ shows an enlarged cross-sectional view of an exemplary portion for the a-QFN package structure shown in FIG. 3F. The first cavity 320a is further etched downward to form an accommodating cavity 320a′. Similarly, the first openings S3 are further etched downward to form deeper first openings S3′. Defined by the openings S3′, a plurality of individual inner leads 330 is formed. The depth ratio of the first etching process and the second etching process may range from 1:1 to 1:2, for example. The second etching process is an isotropic etching process, for example. Since the sidewalls of the first openings S3 and the first cavity 320a are at least partially protected, etching is mainly performed to the bottoms of the first openings S3 and the first cavity 320a. In this case, owing to two etching processes, the inner lead 330 has an upper incurved (curved inward) sidewall S3a and a lower incurved sidewall S3b. In other words, the inner lead 330 looks like two trapezoidal prisms stacked together with a protruded belt portion in the middle (FIG. 4).

As described in the embodiments, the inner leads 330 take advantage of the formation of the undercuts from two etching processes to reinforce or optimize the locking capability of the inner leads toward the subsequently formed molding compound. Accordingly, the etching rate, selectivity of the first/second etching process can be finely tuned for optimal performances, so as to control the dimension or the profile of the openings and optimize the shapes of the lead patterns.

So far, the carrier 300 is roughly formed following the formation of the first metal layer 316a, the second metal layer 316b and patterning the substrate 310. The accommodating cavity 320a′ has a central portion 322 and a peripheral portion 324 disposed around the central portion 322. The inner leads 330 are disposed surrounding but separate from the peripheral portion 324. The inner leads 330 may be arranged in rows, columns or arrays. The peripheral portion 324 can function as the ground ring.

Next, referring to the FIG. 3G, at least a chip 350 is attached to the central portion 322 of the accommodating cavity 320a′ with an adhesive layer 340 in-between. Later, a plurality of wires 360 are provided between the chip 350, the ground ring 324 and the inner leads 330. In other words, the chip 350 is electrically connected to the ground ring 324 and the inner leads 330 through the wires 360.

Next, referring to the FIG. 3H, a molding compound 380 is formed to encapsulate the chip 350, the wires 360, the inner leads 330, the ground ring 324, and fill the accommodating cavity 320a′ and the first openings S3′.

Then, referring to the FIG. 31, using the second metal layer 316b as an etching mask, a third etching process is performed toward the lower surface 310b of the carrier 300 to remove a portion of the substrate 310, so that the carrier 300 is etched through to expose the molding compound 380 filled inside the first openings S3′ and simultaneously form a plurality of second openings S4. Owing to the formation of the second openings S4, a plurality of outer leads 336 is defined and the inner leads 330 are electrically isolated from one another. That is, after the third etching process, a plurality of leads or contact terminals 318, each consisting of one inner lead 330 and the corresponding outer lead 336, is formed. Besides, the third etching process further defines at least a die pad 320 of the carrier 300. The die pad 320 is surrounded by the leads 318 and isolated from the leads 318 through the second openings S4. On the whole, the leads 318 are electrically isolated from one another through this etching process.

Afterwards, referring to FIG. 3J, a singulation process is performed, so that individual a-QFN package structures 30 are obtained.

FIG. 4 is a schematic cross-sectional view illustrating an advanced quad flat non-leaded (a-QFN) package structure according to another embodiment of the present invention, while one of the inner lead of the a-QFN package structure is shown in an enlarged 3D view on the right. Referring to FIG. 4, in the present embodiment, an advanced quad flat non-leaded (a-QFN) package structure 40 includes a carrier 400, a chip 450, a plurality of wires 460 and a molding compound 480.

The carrier 400 in the present embodiment is, for example, a leadframe. In detail, the carrier 400 includes a die pad 420 and a plurality of leads (contact terminals) 438. The leads 438 include a plurality of inner leads 430 and a plurality of outer leads 436, whereas the inner leads and the outer leads are defined by the molding compound.

Further, the die pad 420 of the carrier 400 further includes at least a ground ring 424. As the ground ring 424 is electrically connected to the die pad 420, the die pad together with the ground ring may function as the ground plane. It should be noted that the position, the arrangement and the amount of the leads 438, relative to the ground ring 424 and the die pad 420 as shown in FIG. 4 are merely exemplificative and should not be construed as limitations to the present invention.

In more details, as shown in the three-dimensional enlarged view at the right, the inner lead 430 in the present embodiment has a hat-shaped guard layer 418 covering at least the top surface and the sidewalls of the metal layer 416a and a portion of the upper sidewall S3a. In the present embodiment, the arrangement or the shape of the inner leads 430 and/or the guard layer 418 are merely exemplificative.

In FIG. 4, the inner leads 430 and the outer leads 436 are exemplarily depicted with curved sidewalls, in order to emphasize the profiles or outlines of the openings with undercuts. Due to the existence of the guard layer, the undercuts occurring below the metal layer leads to more incurved sidewalls of the inner leads, which significantly increase the binding between the leads and the molding compound.

In addition, the molding compound 480 of the a-QFN package structure 40 in the present embodiment encapsulates the chip 450, the wires 460, and the inner leads 430 and fills the gaps between the inner leads 430, while the outer leads 436 and the bottom surface of the die pad 420 are exposed. A material of the molding compound 480 is, for example, epoxy resins or other applicable polymer material.

For the a-QFN package structures according to the above embodiments, the inner leads are fabricated though at least two etching processes and the later etching process fine-tunes the profiles of the inner lead sidewalls before the molding process. In addition, as the metal layer on the inner lead portions is at least partially covered by the guard layer during the etching process, the metal layer is less damaged. The a-QFN package structures in the present embodiments are designed to have better locking capability (i.e. stronger adhesion between the inner leads and the molding compound) to solve the fall-off problems and improve the product reliability.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An advanced quad flat non-leaded package structure, comprising:
a carrier having a die pad, and a plurality of leads disposed around the die pad, wherein each of the plurality of the leads includes an inner lead and an outer lead and at least one inner lead includes a metal layer and a guard layer covering at least a portion of edges and sidewalls of the underlying metal layer, and at least one inner lead includes incurved sidewalls;
a chip, located on the die pad;
a plurality of wires, disposed between the chip and the inner leads; and
a molding compound, encapsulating the chip on the die pad, the wires and the inner leads.

2. The advanced quad flat non-leaded package structure as claimed in claim 1, wherein the guard layer fully covers a top surface and the sidewalls of the underlying metal layer.

3. The advanced quad flat non-leaded package structure as claimed in claim 1, wherein the guard layer further covers a portion of the incurved sidewalls of the inner lead.

4. The advanced quad flat non-leaded package structure as claimed in claim 1, wherein the inner lead has upper incurved sidewalls and lower incurved sidewalls and the guard layer fully covers a top surface and the sidewalls of the underlying metal layer and the upper incurved sidewalls of the inner lead.

5. The advanced quad flat non-leaded package structure as claimed in claim 1, wherein a material of the guard layer comprises an etching-resistant metal material.

6. The advanced quad flat non-leaded package structure as claimed in claim 1, wherein the carrier further comprises at least a ground ring located on the die pad and electrically connected to the chip through the wire.

7. The advanced quad flat non-leaded package structure as claimed in claim 1, wherein a material of the leads comprises nickel, gold, palladium or a combination thereof.

8. The advanced quad flat non-leaded package structure as claimed in claim 1, wherein the inner lead has the incurved sidewalls with an incurved distance less than or equivalent to 0.5 microns.

9. A manufacturing method of an advanced quad flat non-leaded package structure, comprising:
providing a substrate having an upper surface and a lower surface;
forming a first metal layer on the upper surface of the substrate;
performing a first etching process to the upper surface of the substrate, using the first metal layer as an etching mask, to form at least a cavity and a plurality of first openings;
forming a guard layer on the first metal layer covering at least edges and sidewalls of the first metal layer;
performing a second etching process to the upper surface of the substrate, using the guard layer and the first metal layer as a mask, to turn the cavity into an accommodating cavity and enlarge the plurality of first openings, wherein a plurality of inner leads are defined by the plurality of enlarged first openings there-between and the inner leads are disposed around the accommodating cavity;
providing a chip to the accommodating cavity of the substrate;
forming a plurality of wires between the chip and the inner leads; and
forming a molding compound over the substrate to encapsulate the chip, the wires and the inner leads.

10. The manufacturing method as claimed in claim 9, wherein the guard layer is formed by plating and a material of the guard layer comprises an etching-resistant metal material.

11. The manufacturing method as claimed in claim 9, wherein the second etching process is an isotropic etching process and the inner leads have incurved sidewalls.

12. The manufacturing method as claimed in claim 9, wherein the first and etching processes are isotropic etching processes, and the guard layer on the first metal layer further covering a portion of sidewalls of the first openings, so that the inner leads have upper incurved sidewalls and lower incurved sidewalls.

13. The manufacturing method as claimed in claim 9, further comprising performing a water jet process before forming the guard layer.

14. The manufacturing method as claimed in claim 9, further comprising forming a second metal layer on the lower surface of the substrate, wherein the first and second metal layers are formed by plating.

15. The manufacturing method as claimed in claim 9, further comprising forming an adhesive layer within the accommodating cavity before the chip is provided.

16. The manufacturing method as claimed in claim 9, further comprising performing a third etching process to the lower surface of the substrate using the second metal layer on the lower surface of the substrate as an etching mask to etch through the substrate until the molding compound filled inside the enlarged first openings is exposed, so as to form a plurality of leads and a die pad.
